(19) United States
(12) Patent Application Publication
(10) Pub. No.: US 2025/0361606 A1
(43) Pub. Date: Nov. 27, 2025

(54) METAL-FLUORIDE THIN FILMS AND DEPOSITION METHODS

(71) Applicant: LOTUS APPLIED TECHNOLOGY, LLC, Hillsboro, OR (US)

(72) Inventor: Eric Dickey, Portland, OR (US)

(21) Appl. No.: 19/216,004

(22) Filed: May 22, 2025

Related U.S. Application Data
(60) Provisional application No. 63/650,770, filed on May 22, 2024.

(51) Int. Cl. C23C 16/30; C23C 14/00; C23C 14/06; C23C 14/35; C23C 16/44; C23C 16/455

(52) U.S. Cl. CPC C23C 16/30; C23C 14/0036; C23C 14/0694; C23C 14/35; C23C 16/4408; C23C 16/45542; C23C 16/45553

(57) ABSTRACT

This disclosure relates to methods for depositing metal-fluoride thin films. In particular, process steps, precursors, and conditions are discussed herein for the formation of ionic metal-fluoride thin films. Barrier films composed of ionic metal-fluoride thin films are also discussed herein.

### RELATED APPLICATIONS

This application claims the benefit of priority under 35 U.S.C. § 119 (e) to U.S. Provisional Patent Application No. 63/650,770, filed May 22, 2024, which is incorporated herein by reference.

### TECHNICAL FIELD

The field of the present disclosure relates generally to thin films and thin film manufacturing processes; and, in particular, to metal-fluoride thin films and methods for producing such thin films.

### BACKGROUND

An overview of conventional ALD processes is provided in Atomic Layer Epitaxy (T. Suntola and M. Simpson, eds., Blackie and Son Ltd., Glasgow, 1990), which is incorporated herein by reference. Numerous patents and publications describe the use of plasma in connection with thin film deposition techniques, including atomic layer deposition (ALD) and sequential chemical vapor deposition.

Radicals (also sometimes called “free radicals”) are unstable atomic or molecular species having an unpaired electron. For example, hydrogen gas exists principally in diatomic molecular form, but molecular hydrogen may be split into atomic hydrogen radicals each having an unpaired electron. Many other radical species are known. In embodiments described herein, the radicals produced and used in the thin film deposition process may include highly reactive radical gas species formed of a single element such as hydrogen, nitrogen, oxygen (e.g., ozone), or chlorine, as well as compound radicals such as hydroxide (OH). Radicals and other atomic species may be generated in a plasma.

U.S. Pat. No. 8,187,679, titled “Radical-Enhanced Atomic Layer Deposition System and Method,” incorporated herein by reference, describes systems and methods for ALD in which oscillating, reciprocating, or circular movement of a substrate can be employed to accomplish ALD processes using precursor radicals that are continuously introduced into a reaction space by a steady-state radical source. The gaseous radical species is maintained in a radicals zone within the reaction chamber while a precursor gas is introduced into a precursor zone. The precursor zone is spaced apart from the radicals zone to define a radical deactivation zone therebetween.

Many chemistries for plasma-enhanced ALD (PEALD) have been proposed, and many more need to be developed in view of the need for efficient production of high-quality thin films in semiconductor manufacturing and other industries.

### BRIEF DESCRIPTION OF THE DRAWINGS

The embodiments disclosed herein will become more fully apparent from the following description and appended claims, taken in conjunction with the accompanying drawings. The drawings depict primarily generalized embodiments (and are not necessarily to scale), which embodiments will be described with additional specificity and detail in connection with the drawings in which:

FIG. 1 illustrates a cross-sectional view of a generalized example of a pulse reactor configured to perform the methods disclosed herein.

FIG. 2 illustrates an overview of a generalized example of a spatial ALD reactor configured to perform the methods disclosed herein.

FIG. 3 illustrates an overview of a generalized example of a Plasma Assisted Reactive Magnetron Sputtering (PARMS) reactor configured to perform the methods disclosed herein.

### DETAILED DESCRIPTION

Disclosed herein are processes for thin film deposition. This disclosure relates to metal-fluoride thin films and to plasma-enhanced atomic layer deposition methods for depositing metal-fluoride thin films. In particular, process steps, precursors, and conditions are discussed herein for the formation of ionic metal-fluoride thin films.

Atomic Layer Deposition (ALD) and chemical vapor deposition (CVD) can utilize the same precursors. However, in contrast to CVD, ALD involves a sequential exposure of a surface to the precursors. Additional steps, including purge steps, can occur in between precursor exposures, reducing the reaction byproducts trapped in the thin film of product produced by the chemical reactions.

Additionally, ALD provides conformal films, even in high-aspect ratio features. ALD reactions tend to coat any surface sequentially exposed to the precursors, including the walls of the reaction chamber and any other equipment present in the reaction chamber. Therefore, ALD has typically been performed in a reaction chamber separate from other processing equipment. This adds to the overall expense of a manufacturing process involving ALD.

Disclosed herein are methods for depositing thin films, where the ALD process can be used to generate ionic metal-fluoride thin films. The methods include providing a substrate to be coated and then repeatedly and sequentially: exposing the substrate to a metal-containing precursor and exposing the substrate to a plasma generated from a mixture of process gases comprising one or more gaseous oxygen-containing compounds and one or more gaseous fluorine-containing compounds. The metal of the metal-containing precursor preferentially forms an ionic bond with fluorine over a covalent bond. A first step results in some of the metal-containing precursor adsorbing on the substrate as an adsorbed metal-containing precursor. A second step results in at least some of the adsorbed metal-containing precursor reacting with the plasma to form an ionic metal-fluoride-containing product. After multiple cycles a thin film of the ionic metal-fluoride-containing product is formed on the substrate. The terms “first step” and “second step” are merely for convenience. The order of the steps is not important. The key being that the steps are alternated.

The methods of depositing the metal on the substrate during the first step may include non-precursor-based processes, such as sputtering or reactive sputtering. Accordingly, the first step may include repeatedly and sequentially: exposing the substrate to a metal deposition, resulting in some (e.g., particles) of the metal depositing on the substrate as a deposited metal (e.g., as a thin film of deposited metal), a deposited metal-containing compound, or both; OR exposing the substrate to a metal-containing precursor resulting in some of the metal-containing precursor adsorbing on the substrate as an adsorbed metal-containing precursor; OR exposing the substrate to both the metal deposition and the metal-containing precursor.

Likewise, the second step may include exposing the substrate to a plasma generated from a mixture of process gases comprising one or more gaseous oxygen-containing compounds and one or more gaseous fluorine-containing compounds, wherein the deposited metal, the metal of the deposited metal-containing compound, the metal of the adsorbed metal-containing precursor, or combinations thereof, preferentially forms an ionic bond with fluorine over a covalent bond, resulting in at least some of the deposited metal, the metal of the deposited metal-containing compound, the metal of the adsorbed metal-containing precursor, or combinations thereof, reacting with the plasma to form an ionic metal-fluoride-containing product. After multiple cycles of the first and second steps a thin film of the ionic metal-fluoride-containing product is formed on the substrate.

As used herein, the terms “ionic” and “covalent” are given their conventional meanings. It is understood that chemical bonds are typically not purely “ionic” or “covalent.” A bond that is primarily ionic is considered ionic. Likewise, a bond that is primarily “covalent” is considered covalent. Fluorine has an electronegativity of 4.0. Typically, metals with an electronegativity less than 2.0 will form an ionic bond with fluorine. Certain metals, such as transition metals, can have multiple oxidation states. At lower oxidation states, the transition metals will tend to form ionic bonds with fluorine. At higher oxidation states, certain transition metals may tend to form covalent bonds with fluorine. When reference is made herein to a metal preferentially forming an ionic bond with fluorine over a covalent bond, it should be understood that reference is being made to the metal at an oxidation state that preferentially form an ionic bond with fluorine over a covalent bond under the process conditions present.

In some embodiments, exposing the substrate to the metal deposition may include sputtering or reactive sputtering the metal on the substrate for a short duration of time. Thus, exposing the substrate to the metal deposition may expose the substrate to particles of a metal or a metal-containing compound which impinge on or contact the substrate, and deposit on the substrate as a thin film of the metal or metal-containing compound. For example, reactive sputtering may include sputtering the metal in an oxygen-containing atmosphere, nitrogen-containing atmosphere, or both, whereby a metal-containing compound comprising a metal oxide, a metal nitride, or combination thereof is deposited on the substrate. In this embodiment, exposing the substrate to the plasma generated from the mixture of process gases comprising one or more gaseous oxygen-containing compounds and one or more gaseous fluorine-containing compounds, results in at least some of the metal oxide, the metal nitride, or combinations thereof, forming the ionic metal-fluoride-containing product. Sputtering or reactive sputtering for a short period of time may include the short duration of time comprises 0.01 second to 1 second, from 0.1 second to 0.5 second, or for about 0.1 second. In this embodiment, the substrate may include an anode or may be proximal to an anode and the substrate may be moved relative to a cathode. The cathode may include a sputtering target or may be proximal a sputtering target. The speed at which the substrate is moved may be used to control the length of time the substrate is exposed to sputtering. The cathode may include a magnetron sputtering cathode.

Repeatedly and sequentially exposing the substrate to the metal deposition or the metal-containing precursor and exposing the substrate to the plasma may include repeatedly moving the substrate, repeatedly moving a plasma source relative to the substrate, or both. Repeatedly moving the substrate may include repeatedly transporting the substrate through different zones within one or more reaction chambers, such as the zones of U.S. Pat. No. 8,187,679, titled “Radical-Enhanced Atomic Layer Deposition System and Method,” incorporated herein by reference. In particular, the different zones may include a plasma zone and either a sputtering zone, a metal-containing precursor zone, or both precursor and sputtering zones.

In embodiments including exposure of the substrate to the metal-containing precursor, the methods may include exposing the absorbed metal-containing precursor to an oxygen-containing atmosphere, nitrogen-containing atmosphere, oxygen-containing plasma, nitrogen-containing plasma, or combinations thereof (such as via a thermal atomic layer deposition process or a plasma-enabled atomic layer deposition process), wherein at least a portion of the adsorbed metal-containing precursor is converted to a metal oxide, a metal nitride, or combination thereof. In such embodiments, exposing the substrate to the plasma generated from the mixture of process gases comprising one or more gaseous oxygen-containing compounds and one or more gaseous fluorine-containing compounds, results in at least some of the metal oxide, the metal nitride, or combinations thereof, forming the ionic metal-fluoride-containing product.

Any plasma generator may be used, such as a capacitively or inductively coupled radio frequency (RF) plasma generator, direct-current (DC) plasma generator, or pulsed plasma generator. For high-speed spatial ALD reactors (e.g., reactors with a plasma exposure time of 1 second or less), it can be beneficial to use a DC plasma generator or pulsed plasma generator. DC and pulsed plasma generators tend to produce more free radicals than RF plasma generators and can provide enough free radicals in the plasma during the short exposure period that results from a high-speed spatial ALD process.

Moving the plasma source may involve moving the plasma source in a path parallel to the substrate.

The geometry of the substrate is not limited. For example, the substrate may be a curved surface, a flat surface, or a roll-to-roll film.

The process gases may also include a background gas. The background gas, under the process conditions present, is preferably substantially non-reactive with the gaseous oxygen-containing compounds, the gaseous fluorine-containing compounds, and the metal-containing precursor.

Non-limiting examples of gaseous oxygen-containing compounds include air, oxygen (O₂), carbon monoxide (CO), carbon dioxide (CO₂), nitrogen monoxide (NO), nitrogen dioxide (NO₂), a mixture of N₂ and CO₂, ozone (O₃), hydrogen peroxide (H₂O₂), water (H₂O), alcohols, including methanol and ethanol, and combinations of the foregoing.

The gaseous fluorine-containing compounds are preferably fluorocarbons, including perfluorocarbons such as carbon tetrafluoride, and combinations thereof.

Non-limiting examples of the metal-containing precursor include: a pure metal (e.g., magnesium, manganese, zinc, cadmium, and mercury); metal hydrides (e.g., silane, disilane, germane, aluminum hydride-trimethylamine, and selenium hydride); metal halides (e.g., fluorides, chlorides, bromides, and iodides, such as tungsten hexafluoride, titanium tetrachloride, hafnium tetrachloride, tin tetrachloride, vanadium oxide trichloride, and chromium dichloride dioxide); metal alkoxides (e.g., aluminum ethoxide, isopropoxydimethylaluminum, trimethylborate, hafnium tert-butoxide, tetra (1-methoxy-2-methyl-2-propoxy) hafnium, niobium ethoxide, bis(1-dimethylamino-2-methyl-2-propoxy) nickel (II), lead (II) tert-butoxide, tetraethylorthosilicate, tris (tert-butoxy) silanol, tris (tert-pentoxy) silanol, tantalum ethoxide, titanium methoxide, titanium ethoxide, titanium isopropoxide, and vanadyl isopropoxide); metal β-diketonates (e.g., Ba(thd)₂, Ce(thd)₄, Mg(thd)₂, Mn(thd)₃, Co(acac)₂, Co(acac)₃, Co(thd)₃, Nd(thd)₃, Ni(acac)₂, Ni(thd)₂, Pb(thd)₂, Cr(acac)₃, Cu(hfac)₂, Cu(thd)₂, Dy(thd)₂, Pd(hfac)₂, Pd(thd)₂, Pt(acac)₃, Er(thd)₃, Eu(thd)₃, Fe(acac)₃, Ru(thd)₃, Ru(od)₃, Sc(thd)₃, Fe(thd)₃, Gd(thd)₃, Ho(thd)₃, Sm(thd)₃, Sr(thd)₂, Sr(methd)₂, Ir(acac)₃, La(thd)₃, Tm(thd)₃, and Y(thd)₃); metal alkylimides and alkylamides (e.g., tris(dimethylamido) aluminum, hexakis (dimethylamido)dialuminum, tris(bis(trimethylsilyl) amido)bismuth, tetrakis(dimethylamido) hafnium, tetra(ethylmethylamido) hafnium (TEMAH), tetrakis(diethylamido) hafnium (TDEAH), tris(bis(trimethylsilyl) amido) lanthanum, tris(bis(trimethylsilyl) amido) praseodymium, pentakis (dimethylamido) tantalum, pentakis (diethylamido) tantalum, (tert-butylimido)tris(diethylamido) tantalum, tetrakis(dimethylamido) titanium, tetra(ethylmethylamido) titanium (TEMAT), bis(tert-butylimido)bis(dimethylamido) tungsten, bis(bis(trimethylsilyl) amido) zinc, tetrakis(dimethylamido) zirconium, tetra(ethylmethylamido) zirconium (TEMAZ), and tetrakis(diethylamido) zirconium (TDEAZ)); metal amidinates (e.g., Ag₂(tBu₂-amd)₂, Ca(tBu₂-amd)₂, Co(iPr₂-amd)₂, Lu(Et₂-fmd)₃, Lu(Et₂-amd)₃, Mg(tBuzamd)₂, Co(tBuEt-amd)₂, Cr(Et₂-amd)₃, Cu₂(iPr₂-amd)₂, Cu₂amd)₂, Mg (iPr₂-amd)₂, Mn (tBu₂-pemd)₂, Ni(tBu₂-amd)₂, Pr(iPr₂-amd)₃, Cu₂(sBu₂-amd)₂, Er(tBu₂-amd)₃, Fe(iPr₂-amd)₂, Sc(Et₂-amd)₃, Sr(tBu₂-amd)₂, Fe(tBuEt-amd)₂, Ga(Et₂-amd)₃, Gd(iPr₂-amd)₃, Hf(Me₂-fmd)₄, Ti(iPr₂-amd)₃, V(Et₂-amd)₃, V(iPr₂-amd)₃, Hf(Mez-pmd)₄, Hf(Me₂-bmd)₄, La(iPr₂-fmd)₃, Y(iPr₂-amd)₃, Zn(iPr₂-amd)₂, Zr(Me₂-fmd)₄, Zr(Me₂-pmd), La(iPr₂-fmd)₃, La(tBu₂-fmd)₃, and Zr(Mez-bmd)₄); metal alkyls (e.g., methyl, ethyl or propyl ligands on boron, aluminum, silicon, zinc, gallium, germanium, cadmium, indium, tin, antimony, tellurium, mercury, or bismuth); metal cyclopentadienyls (e.g., cyclopentadienyl, methylcyclopentadienyl, pentamethylcyclopentadienyl, ethylcyclopentadienyl, or isopropylcyclopentadienyl ligands on magnesium, calcium, scandium, titanium, strontium, yttrium, zirconium, barium, latrium, hafnium, manganese, iron, cobalt, nickel, ruthenium, platinum, indium, praseodymium, erbium, or lutetium); and combinations thereof. As used herein, “acac” refers to acetylacetonate, “hfac” refers to 1,1,1,5,5,5-hexafluoro-acetylacetonate, “thd” refers to 2,2,6,6-tetramethyl-heptane-3,5-dionate, “od” refers to octane-2 4-dionate, “methd” refers to 1-(2-methoxyethoxy)-2,2,6,6-tetramethyl-heptane-3,5-dionate, “amd” refers to acetamidinate, “fmd” refers to formamidinate, “pmd” refers to propionamidinate, “bmd” refers to butyramidinate, and “pemd” refers to pentylamidinate.

The volume percent of the one or more gaseous fluorine-containing compounds in the process gas may be at least 0.1%, or at least 1.0%, or at least 2.0%, or 0.1% to 99.0%, for example. The volume percent of the one or more gaseous oxygen-containing compounds in the process gas may be at least 1.0% or 1.0% to 99.9%, for example. Without wishing to be bound by theory, it is believed that the oxygen radicals generated in the plasma remove carbon from the product thin film. As a result, the percentage of carbon on an atomic basis in the ionic metal-fluoride-containing product may be less than 20%, or less than 15%, or less than 10%, or less than 5%, or 0.1% to 10%, for example. Beneficially, the percent carbon in the thin film product may be less than that produced by a comparable ALD process that does not utilize a gaseous oxygen-containing compound in the plasma. Experiments conducted with O₂ as the gaseous oxygen-containing compound indicated that at least 1% O₂ by volume was required for adequate carbon removal from the product thin film. Gaseous oxygen-containing compounds with a single oxygen atom per molecule, such as carbon monoxide (CO), nitrogen monoxide (NO), and water (H₂O), may require higher volume percents to achieve adequate carbon removal from the product thin film.

Again, without wishing to be bound by theory, it is believed that the ionic bond between fluorine and the metal outcompetes bonding between oxygen and the metal. Oxide may be temporarily formed in the product thin film; however, the fluorine atoms displace the oxygen, even in the presence of more oxygen than fluorine in the plasma. As a result, the percentage of oxygen on an atomic basis in the ionic metal-fluoride-containing product may be less than 20%, or less than 15%, or less than 10%, or less than 5%, or 1% to 20%, for example, even when significantly more oxygen than fluorine is present in the plasma.

One advantage of using fluorocarbons, such as carbon tetrafluoride, as the gaseous fluorine-containing compounds in the processes disclosed herein, the impurities in the thin film product may be less, as compared to when non-fluorocarbon fluorine-containing compounds are used. For example, when sulfur hexafluoride was used in a high-speed plasma-enabled spatial ALD process, significant sulfur residue was incorporated into the thin film product. Therefore, the thin films produced by the processes disclosed herein may produce thin film products with less impurities, even when the spatial ALD processes are operated at high speed (e.g., exposure times of 1 second or less). The percentage of impurities, other than oxygen or carbon, on an atomic basis in the ionic metal-fluoride-containing product may be less than 20%, or less than 15%, or less than 10%, or less than 5%, or 1% to 20%, for example.

Another advantage of using fluorocarbons, such as carbon tetrafluoride, as the gaseous fluorine-containing compounds in the processes disclosed herein, is that the homogeneity of the thin film product may be greater, as compared to when non-fluorocarbon fluorine-containing compounds are used. For example, use of hydrogen fluoride as the fluorine source in a plasma-enabled ALD process may result in significant metal-rich clusters in the film product, as opposed to a homogeneous ionic metal-fluoride product. In the thin films produced with fluorocarbons, the ionic metal-fluoride product may have 10% or less, or 9% or less, or 8% or less, or 7% or less, or 6% or less, or 5% or less, or 4% or less, or 3% or less, or 2% or less, or 1% or less, metal-rich clusters in the thin film on an atomic basis.

Non-limiting examples of the ionic metal-fluoride-containing products include AlF₃, LiF, CaF₂, SrF₂, MgF₂, ScF₃, YF₃, and ZnF₂; a lanthanide fluoride, such as LaF₃, CeF₃, PrF₃, NdF₃, PmF₃, SmF₃, EuF₃, GdF₃, TbF₃, DyF₃, HoF₃, ErF₃, TmF₃, YbF₃, or LuF₃; and combinations thereof. A thin film of the ionic metal-fluoride-containing product may be formed on a portion of the substrate or the entire exposed surface of the substrate. The ionic metal-fluoride-containing product may include both a first metal and a second metal, wherein both the first metal and the second metal preferentially form ionic bonds with fluorine, over covalent bonds. Repeatedly and sequentially exposing the substrate to the metal-containing precursor may include exposing the substrate to a first metal-containing precursor and a second metal-containing precursor, such as, for example, a rare-earth metal precursor (e.g., a rare earth metal cyclopentadienyl) and a metal alkyl (e.g., trimethyl aluminum).

The plasma is preferably generated proximal the exposed surface of the substrate. Alternatively, the plasma could be generated remotely and the plasma species directed towards the exposed surface of the substrate.

Repeatedly and sequentially exposing the substrate to the plasma may involve exposing the substrate to the plasma for 0.01 second to 1 second, or from 0.1 second to 0.5 second, or for about 0.1 second, for example. Likewise, repeatedly and sequentially exposing the substrate to the metal deposition or the metal-containing precursor may involve exposing the substrate to the metal deposition or the metal-containing precursor for 0.01 second to 1 second, or from 0.1 second to 0.5 second, or for about 0.1 second, for example. Additionally, both the plasma exposure step and the metal-containing precursor step/metal deposition step may each be for 1 second or less. In many typical reactors, the substrates would experience the same exposure time during each exposure step; however, reactors and/or process controls could be configured to provide different lengths of time for each exposure step. In some embodiments, the exposures may exceed 1 second, although such long exposures might unnecessarily increase the time required to deposit a thin film of equivalent thickness.

The methods disclosed herein may include providing a reaction chamber; and pressurizing the reaction chamber, at least partially, with a single dose of the metal-containing precursor gas or continuously pumping the metal-containing precursor gas into the reaction chamber. The methods may include first evacuating the reaction chamber to 0.000001 Torr to 100 Torr prior to pressurizing the reaction chamber. The reaction chamber may be pressurized to pressures ranging from 10 Torr to atmospheric pressure with the metal-containing precursor, the process gas (including any background gases), additional gases, or mixtures thereof. Thus, the term “pressurized” and “pressurizing,” as used herein, indicate that pressure is increased relative to some beginning pressure or vacuum. And while these terms might include pressures above atmospheric pressure, the terms “pressurized” and “pressurizing” should not be limited to increasing the pressure above atmospheric pressure or to pressures greater than atmospheric pressure.

The plasma source may include physical barriers (e.g., a shroud), fluidic barriers (e.g., gas curtains), or combinations of both to allow radical recombination (i.e., plasma deactivation) prior to the plasma gases exiting areas proximal to the plasma source, to limit precursor near the plasma generator, or both. Examples of physical barriers that could be used are the shrouds disclosed in U.S. patent application Ser. No. 18/456,806, filed Aug. 28, 2023, now published as U.S. Patent Application Publication No. US 2024/0368760 A1, titled “Methods and Systems for Inhibiting Precursor Interactions During Radical-Enhanced Atomic Layer Deposition,” which is incorporated herein in its entirety. Additional examples of barriers and systems that could be used with the methods disclosed here are the barriers and systems disclosed in U.S. Pat. No. 8,187,679, titled “Radical-Enhanced Atomic Layer Deposition System and Method,” which is incorporated herein by reference.

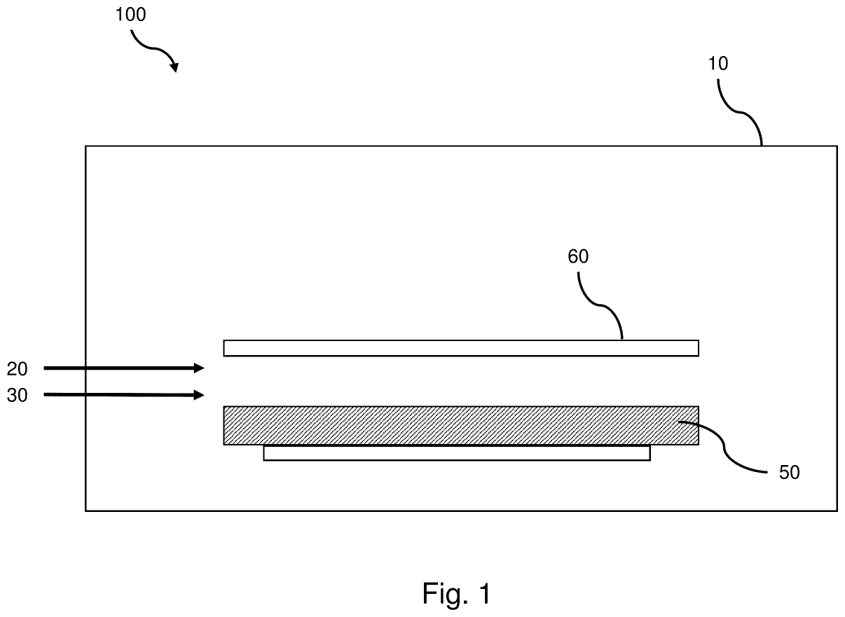

It should be understood that the methods disclosed herein may be performed with plasma-enabled ALD reaction chambers, including pulse and spatial ALD reaction chambers. FIG. 1 illustrates a cross-sectional view of one example of a generalized pulse reactor configured to perform the methods disclosed herein. The system 100 includes a reaction chamber 10, including an inlet 20 for introducing a metal-containing precursor gas into the reaction chamber 10 and an inlet 30 for introducing a process gas containing the gaseous oxygen-containing compound and the gaseous fluorine-containing compound (alternatively, the different components of the process gas may each have its own inlet). A plasma generator 60 is configured to generate a plasma from the process gas, when the process gas is present.

In the pulse reaction chamber 10 the ALD half-reactions are separated in time, but they occur in the same physical space or location. The reaction chamber 10 is evacuated and then the metal-containing precursor gas is introduced via the inlet 20. The metal-containing precursor is maintained in the reaction chamber 10 for a sufficient time to allow complete adsorption (e.g., chemisorption) of the metal-containing precursor to the substrate 50. Beneficially, this will tend to be at most one molecular layer of the precursor (in practice, multiple ALD steps are often required before a complete molecular layer is formed, due to limitations on initial binding sites, steric hindrance between adjacent precursors, and other issues). The substrate may optionally be at a different temperature from the other surfaces of the reaction chamber 10, thereby promoting preferential adsorption kinetics of the metal-containing precursor to the substrate 50.

After a selected time, the reaction chamber 10 may be evacuated again (and the metal-containing precursor recaptured and recycled) and then a purge gas (not shown) introduced to further remove residual unadsorbed precursor from the reaction chamber 10.

Next, the process gas is introduced via the inlet 30 and the plasma generator 60 is activated. The substrate 50 may be grounded and the plasma generator 60 may comprise an electrode. Upon activation, such as by energizing the electrode with a DC voltage, a plasma forms from the process gas located between the electrode and the substrate 50. The process gas plasma reacts with the adsorbed metal-containing precursor to form up to one molecular layer of the desired ionic metal-fluoride-containing product on the substrate 50.

After a selected time, the reaction chamber 10 may be evacuated again (and the process gas recaptured and recycled) and then a purge gas (not shown) introduced to further remove residual process gas from the reaction chamber 10 along with any byproducts of the reaction. The foregoing process is repeated until a desired thickness of the ionic metal-fluoride-containing product is achieved.

One of ordinary skill in the art, with the benefit of the present disclosure, will understand that a variety of additional components and process steps, common to pulse ALD may be utilized with the reaction chamber 10 and associated process.

In FIG. 1, the plasma generator 60 is located within the reaction chamber 10; however, the plasma generator 60 could also be located elsewhere, including outside the reaction chamber 10, and the plasma produced thereby directed via the process gas supply and towards the substrate 50. For example, the plasma generator 60 may be located in a flow path of the process upstream of the inlet 30.

In other embodiments, the plasma generator 60 may be a UV light source or other high-intensity light source.

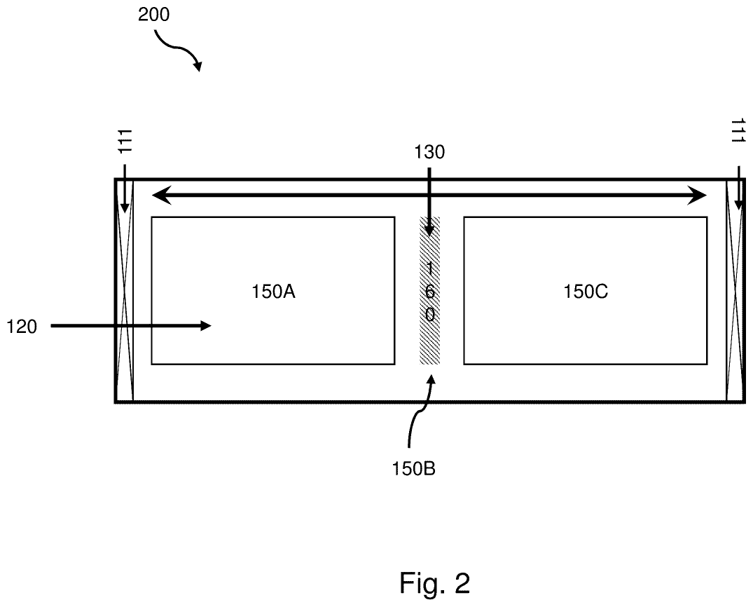

Pulse reactors have certain benefits; however, throughput can be increased with a spatial ALD reactor. FIG. 2 illustrates an exemplary system 200 with a generalized linear spatial ALD reaction chamber 110. A plasma generator 160 (depicted as a rectangle for simplicity) is placed centrally along the shuttle path of the substrate (position 150B). A single substrate (not shown) is loaded into the starting position 150A, the valves 111 are closed, and the reaction chamber 110 is pumped down to a desired pressure. Metal-containing precursor is then pumped into the reaction chamber 110 via an inlet 120 until a desired pressure or partial pressure is achieved. The plasma generator 160 is energized and the process gas is supplied near the plasma generator 160 via an inlet 130. The substrate is shuttled from the starting position 1150A to the final position 1150C and back to the starting position 1150A. The precursor gas fills the reaction chamber 110 and is present in the starting position 150A and the final position 150C. The substrate residence time in the starting position 150A and the final position 150C is sufficient for adsorption of the precursor the substrate. Physical and/or fluidic barriers (not shown) may be present to limit metal-containing precursor presence near the plasma generator 160 and/or to limit migration of the process gas into the other zones (e.g., starting position 150A and final position 150C). A complete ALD reaction occurs each time the substrate passes underneath the plasma generator 160. The substrate can be shuttled back-and-forth non-stop until a desired thin film growth is achieved.

For embodiments utilizing sputtering or reactive sputtering, a Plasma Assisted Reactive Magnetron Sputtering (PARMS) reactor can be utilized to perform the methods disclosed herein.

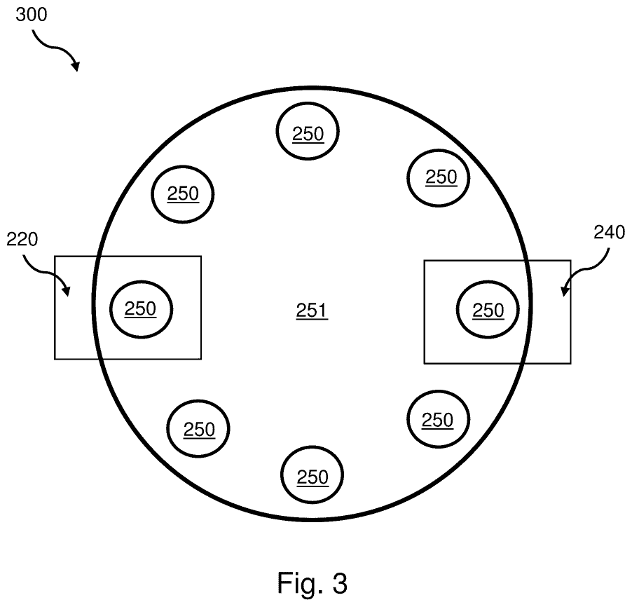

FIG. 3 illustrates an overview of a generalized example of a PARMS reactor configured to perform the methods disclosed herein. FIG. 3 illustrates an exemplary rotary system 300. The system 300 includes a disc-shaped platen or carrier 251 that rotates about a central axis and is the positioning system. Substrates 250, such as disc-shaped silicon wafers, can be mounted on the surface of the platen 251. Substrates of other types and shapes may also be utilized. The platen 251 spins about its axis within a reaction chamber (not shown). The substrates are transported along a circular transport path sequentially passing through the sputter zone 220 and the plasma zone 240. The mixture of process gases comprising one or more gaseous oxygen-containing compounds and one or more gaseous fluorine-containing compounds are supplied to the plasma zone 240 and a plasma created using electrodes (not shown). The speed of the platen 251 governs the residence time of each substrate 250 within the respective zones. In addition to a disc-shaped platen, a cylindrical platen may be used. Substrates could be rotated through different zones located around the perimeter of the cylinder.

U.S. Pat. No. 4,851,095, titled “Magnetron Sputtering Apparatus and Process,” U.S. Pat. No. 5,225,057, titled “Process for Depositing Optical Films on both Planar and Non-Planar Substrates,” and U.S. Pat. No. 5,879,519, titled “Geometries and Configurations for Magnetron Sputtering Apparatus,” all of which are incorporated herein by reference, describe various sputter coating systems and processes utilizing a rotary device (e.g., drum or disk) mounted within a vacuum chamber, where at least one sputter device is located adjacent the rotary device and at least one plasma generating device is located adjacent the rotary device at a different location. These patents provide examples of PARMS reactors that could be utilized with the embodiments disclosed herein that involve sputtering or reactive sputtering. The rotary device could be used as a carrier for substrates and control repeatedly and sequentially exposing the substrates to the method steps disclosed herein. The sputter devices could be used for exposing the substrate to the metal deposition. Likewise, the plasma generating devices could be used for exposing the substrate to a plasma generated from a mixture of process gases comprising one or more gaseous oxygen-containing compounds and one or more gaseous fluorine-containing compounds. Accordingly, existing PARMS reactors could be utilized as part of methods and systems for making the plasma-enabled sputter-deposited ionic metal fluoride thin films disclosed herein and could also be used to perform the sputtering-related methods disclosed herein.

It should be understood that a variety of spatial deposition systems may be used with the methods disclosed herein, including linear, rotary, cylindrical, and roll-to-roll deposition systems.

Barrier films are disclosed herein, including barrier films comprising a plasma-enabled atomic layer deposition produced homogeneous ionic metal fluoride thin film having 10% or less, or 9% or less, or 8% or less, or 7% or less, or 6% or less, or 5% or less, or 4% or less, or 3% or less, or 2% or less, or 1% or less metal-rich clusters in the thin film on an atomic basis.

Barrier films comprising a plasma-enabled sputter-deposited ionic metal fluoride thin film are also disclosed herein. The sputter-deposited ionic metal fluoride thin films may have improved adhesion, reduced stress, increased density, and/or improved stoichiometry as compared to ionic metal fluoride thin films made other ways. The ionic metal fluoride thin film may include a homogeneous ionic metal fluoride thin film having 10% or less, or 9% or less, or 8% or less, or 7% or less, or 6% or less, or 5% or less, or 4% or less, or 3% or less, or 2% or less, or 1% or less metal-rich clusters in the thin film on an atomic basis.

The barrier films may have a fluorine to oxygen ratio on an atomic basis of greater than or equal to 1:1, or greater than or equal to 2:1, or greater than or equal to 3:1, or greater than or equal to 4:1, or greater than or equal to 5:1, or greater than or equal to 6:1, or greater than or equal to 7:1, or greater than or equal to 8:1, or greater than or equal to 9:1, or greater than or equal to 20:1, or greater than or equal to 99:1. Preferably, barrier films have a fluorine to oxygen ratio on an atomic basis of greater than or equal to 4:1, or greater than or equal to 5:1, or greater than or equal to 6:1, or greater than or equal to 7:1, or greater than or equal to 8:1, or greater than or equal to 9:1, or greater than or equal to 20:1, or greater than or equal to 99:1. Ionic metal fluoride-rich thin films are preferred; however, thin films with as much as 50% oxide, on an atomic basis, can be produced. The barrier films may have a carbon content of less than 20%, or less than 15%, or less than 10%, or less than 5%, on an atomic basis. The ionic metal fluoride thin film in the barrier film may include one or more of AlF₃, LiF, CaF₂, SrF₂, MgF₂, ScF₃, YF₃, ZnF₂, a lanthanide fluoride, such as LaF₃, CeF₃, PrF₃, NdF₃, PmF₃, SmF₃, EuF₃, GdF₃, TbF₃, DyF₃, HoF₃, ErF₃, TmF₃, YbF₃, or LuF₃, and combinations thereof.

In a particular example, the ionic metal fluoride thin film may be an AlF₃ thin film with a refractive index of 1.25 to 1.50 at 633 nm, or 1.30 to 1.45 at 633 nm, or 1.35 to 1.40 at 633 nm, or about 1.38 at 633 nm. Notably, 633 nm is the He—Ne laser wavelength commonly used in ellipsometry. The AlF₃ thin film may have a wet etch rate in 50:1 H₂O:Hf of less than 0.5 nm per minute.

Products having an outer surface coated with any of the barrier films disclosed herein are also encompassed by this disclosure. For example, the barrier films may function as optical coatings on a variety of optical products, including as an optical coating on a lens. Ionic metal fluoride thin films tend to have excellent light transmission properties and can be used in the infrared (IR) and ultraviolet (UV) range.

### Example 1

A thin film of AlF₃ (an “ionic metal-fluoride product”) was formed on a silicon wafer using trimethylaluminum (TMA) (a metal-containing precursor) and a mixture of O₂ (a gaseous oxygen-containing compound) and CF₄ (a gaseous fluorine-containing compound) as the process gas (1.0 Torr O₂, 0.050 Torr CF₄). A DC plasma with a current of 0.8 amps was generated using the process gas. A rotary ALD reactor similar to FIG. 1 of U.S. Pat. No. 8,187,679, titled “Radical-Enhanced Atomic Layer Deposition System and Method,” was used for the experiment. Rotation speed was 60 rotations per minute (RPM) or approximately one rotation per second. Exposure of the substrate to the metal-containing precursor and the process gas plasma were each roughly 0.1 second per rotation. Each rotation resulted in a complete ALD cycle. Five hundred (500) cycles produced thin film of AlF₃ having a thickness of 71 nm. The composition of the thin film was confirmed by evaluating the refractive index and wet etch rate. The product thin film had a refractive index of 1.38 at 633 nm (similar to literature values for AlF₃) and a wet etch rate in 50:1 H₂O:Hf of less than 0.5 nm per minute (similar to literature values for AlF₃).

Without further elaboration, it is believed that one skilled in the art can use the preceding description to utilize the present disclosure to its fullest extent. The examples and embodiments disclosed herein are to be construed as merely illustrative and exemplary and not a limitation of the scope of the present disclosure in any way. It will be apparent to those having skill in the art, and having the benefit of this disclosure, that changes may be made to the details of the above-described embodiments without departing from the underlying principles of the disclosure herein.

1. A method of forming a thin film, the method comprising:
providing a substrate to be coated;
repeatedly performing a cycle, comprising the sequential steps of:
(a) exposing the substrate to a metal deposition, resulting in some of the metal depositing on the substrate as a deposited metal, a deposited metal-containing compound, or both; OR
exposing the substrate to a metal-containing precursor resulting in some of the metal-containing precursor adsorbing on the substrate as an adsorbed metal-containing precursor; OR
exposing the substrate to both the metal deposition and the metal-containing precursor; and
(b) exposing the substrate to a plasma generated from a mixture of process gases comprising one or more gaseous oxygen-containing compounds and one or more gaseous fluorine-containing compounds,
wherein the deposited metal, the metal of the deposited metal-containing compound, the metal of the adsorbed metal-containing precursor, or combinations thereof, preferentially forms an ionic bond with fluorine over a covalent bond, resulting in at least some of the deposited metal, the metal of the deposited metal-containing compound, the metal of the adsorbed metal-containing precursor, or combinations thereof, reacting with the plasma to form an ionic metal-fluoride-containing product;
whereby after multiple cycles a thin film of the ionic metal-fluoride-containing product is formed on the substrate.

2. The method of claim 1, wherein exposing the substrate to the metal deposition comprises sputtering or reactive sputtering the metal on the substrate for a short duration of time.

3. The method of claim 2, wherein the reactive sputtering comprises sputtering the metal in an oxygen-containing atmosphere, nitrogen-containing atmosphere, or both, whereby a metal-containing compound comprising a metal oxide, a metal nitride, or combination thereof, is deposited on the substrate; and wherein exposing the substrate to the plasma generated from the mixture of process gases comprising one or more gaseous oxygen-containing compounds and one or more gaseous fluorine-containing compounds, results in at least some of the metal oxide, the metal nitride, or combinations thereof, forming the ionic metal-fluoride-containing product.

4. The method of claim 2, wherein the short duration of time comprises 0.01 second to 1 second.

5. The method of claim 3, wherein the substrate comprises an anode or is proximal to an anode and wherein the substrate is moved relative to a cathode, wherein the cathode comprises a sputtering target or is proximal a sputtering target, and wherein a speed at which the substrate is moved controls, at least in part, a time length of the short duration of time.

6. The method of claim 5, wherein the cathode comprises a magnetron sputtering cathode.

7. The method of claim 1, wherein:
step (a) comprises exposing the substrate to the metal-containing precursor, and further comprises, after exposing the substrate to the metal-containing precursor, subsequently exposing the adbsorbed metal-containing precursor to an oxygen-containing atmosphere, nitrogen-containing atmosphere, oxygen-containing plasma, nitrogen-containing plasma, or combinations thereof, wherein at least a portion of the adsorbed metal-containing precursor is converted to a metal oxide, a metal nitride, or combination thereof; and
wherein step (b) of exposing the substrate to the plasma results in at least some of the metal oxide, the metal nitride, or combinations thereof, forming the ionic metal-fluoride-containing product.

8. The method of claim 7, wherein exposing the adbsorbed metal-containing precursor to an oxygen-containing atmosphere, nitrogen-containing atmosphere, oxygen-containing plasma, nitrogen-containing plasma, or combinations thereof, comprises a thermal atomic layer deposition process or a plasma-enabled atomic layer deposition process.

9. The method of claim 1, wherein the one or more gaseous fluorine-containing compounds comprise fluorocarbons.

10. The method of claim 1, wherein each cycle includes moving the substrate, moving a plasma source relative to the substrate, or both.

11. The method of claim 1, wherein each cycle includes transporting the substrate through different zones within one or more reaction chambers, including transporting the substrate through a sputter zone and a plasma zone.

12. The method of claim 1, wherein each cycle includes transporting the substrate through different zones within one or more reaction chambers, including transporting the substrate through a metal-containing precursor zone and a plasma zone.

13. The method of claim 1, wherein the plasma is generated from a direct current plasma or pulsed plasma.

14. The method of claim 1, wherein each step (b) of exposing the substrate to the plasma includes exposing the substrate to the plasma for 0.01 second to 1 second; and wherein each step (a) of exposing the substrate to the metal deposition or the metal-containing precursor, or combinations thereof, comprises exposing the substrate to the metal deposition or the metal-containing precursor, or combinations thereof, for 0.01 second to 1 second.

15. The method of claim 1, wherein the one or more gaseous oxygen-containing compounds are selected from the group consisting of air, oxygen (O₂), carbon monoxide (CO), carbon dioxide (CO₂), nitrogen monoxide (NO), nitrogen dioxide (NO₂), a mixture of N₂ and CO₂, ozone (O₃), hydrogen peroxide (H₂O₂), water (H₂O), alcohols, and combinations of the foregoing.

16. The method of claim 1, wherein a volume percent of the one or more gaseous fluorine-containing compounds in the process gas is at least 0.1%; and wherein a volume percent of the one or more gaseous oxygen-containing compounds in the process gas is at least 1.0%.

17. The method of claim 1, wherein the metal-containing precursor comprises: metal hydrides; metal halides; metal alkoxides; metal β-diketonates; metal alkylimides; metal alkylamides; metal amidinates; metal alkyls; metal cyclopentadienyls; or combinations thereof.

18. The method of claim 1, wherein the ionic metal-fluoride-containing product includes one or more of AlF₃, LiF, CaF₂, SrF₂, MgF₂, ScF₃, YF₃, ZnF₂, a lanthanide fluoride, and combinations thereof.

19. The method of claim 1, wherein the process gases further comprise a background gas, wherein the background gas, under the process conditions present, is substantially non-reactive with the one or more gaseous oxygen-containing compounds, the one or more gaseous fluorine-containing compounds, and the metal-containing precursor.

20. The method of claim 1, further comprising generating the plasma proximal an exposed surface of the substrate.

21. The method of claim 1, further comprising purging at least some of the unabsorbed metal-containing precursor from proximal the substrate prior to exposing the substrate to the plasma.

22. The method of claim 1, wherein a thin film of the ionic metal-fluoride-containing product is formed on a portion of the substrate or an entire surface of the substrate.

23. The method of claim 1, wherein step (a) includes exposing the substrate to the metal-containing precursor, and wherein exposing the substrate to the metal-containing precursor comprises exposing the substrate to a first metal-containing precursor and a second metal-containing precursor, and wherein the ionic metal-fluoride-containing product comprises both a first metal and a second metal, and wherein both the first metal and the second metal preferentially form ionic bonds with fluorine, over covalent bonds.

24. A barrier film comprising a homogeneous ionic metal fluoride thin film produced by plasma-enabled thin film deposition, having 10% or less metal-rich clusters in the thin film on an atomic basis.

25. The barrier film of claim 24, having a fluorine to oxygen ratio on an atomic basis of greater than or equal to 2:1.

26. The barrier film of claim 24 having a carbon content of less than 20% on an atomic basis.

27. The barrier film of claim 24 having an oxygen content of less than 20% on an atomic basis.

28. The barrier film of claim 24, wherein the ionic metal fluoride thin film comprises one or more of AlF₃, LiF, CaF₂, SrF₂, MgF₂, ScF₃, YF₃, ZnF₂; LaF₃, CeF₃, PrF₃, NdF₃, PmF₃, SmF₃, EuF₃, GdF₃, TbF₃, DyF₃, HoF₃, ErF₃, TmF₃, YbF₃, LuF₃, and combinations thereof.

29. The barrier film of claim 24, wherein the ionic metal fluoride thin film comprises an AlF₃ thin film with a refractive index of 1.25 to 1.50 at 633 nm.

30. The barrier film of claim 29, wherein the AlF₃ thin film has a wet etch rate in 50:1 H₂O:Hf of less than 0.5 nm per minute.
